(19) United States
(12) Patent Application Publication
(10) Pub. No.: US 2025/0062272 A1
(43) Pub. Date: Feb. 20, 2025

(54) SEMICONDUCTOR MODULE

(71) Applicant: FUJI ELECTRIC CO., LTD., Kawasaki-shi (JP)

(72) Inventors: Tsubasa WATAKABE, Kawasaki-shi (JP); Akihiko IWAYA, Kawasaki-shi (JP); Yoko NAKAMURA, Kawasaki-shi (JP); Yuta TAMAI, Kawasaki-shi (JP); Mai SAITO, Kawasaki-shi (JP)

(73) Assignee: FUJI ELECTRIC CO., LTD., Kawasaki-shi (JP)

(21) Appl. No.: 18/934,226

(22) Filed: Oct. 31, 2024

Related U.S. Application Data
(63) Continuation of application No. PCT/JP2023/036711, filed on Oct. 10, 2023.

(30) Foreign Application Priority Data
Nov. 4, 2022 (JP) 2022-177079

(51) Int. Cl. H01L 23/00; H01L 23/495; H01L 25/07; H05K 1/14

(52) U.S. Cl. CPC H01L 24/40; H01L 23/49562; H01L 24/32; H01L 24/73; H05K 1/142; H01L 25/072; H01L 2224/32227; H01L 2224/32238; H01L 2224/32245; H01L 2224/4005; H01L 2224/40229; H01L 2224/73263; H01L 2924/13055; H01L 2924/35121

(57) ABSTRACT

A semiconductor module, including: a stacked substrate, which includes an insulating plate, and a plurality of circuit boards formed on an upper surface of the insulating plate; a semiconductor element formed on an upper surface of one of the plurality of circuit boards; and a metal wiring board formed on an upper surface of the semiconductor element. The metal wiring board has a plate-shaped bonding portion bonded to the upper surface of the semiconductor element via a bonding material. The plate-shaped bonding portion has a plurality of recessed portions formed on an upper surface thereof, each recessed portion is of a hexagonal shape in a plan view of the semiconductor module.

### CROSS-REFERENCE TO RELATED APPLICATION

This application is a continuation application of International Patent application PCT/JP2023/036711, filed on Oct. 10, 2023, which claims priority to Japanese patent application No. JP 2022-177079, filed on Nov. 4, 2022, the contents of which are incorporated by reference herein in their entirety.

### TECHNICAL FIELD

The present invention relates to a semiconductor module.

### BACKGROUND ART

A semiconductor module has a substrate, on which a semiconductor element such as an insulated gate bipolar transistor (IGBT), a power metal oxide semiconductor field effect transistor (MOSFET), or a free wheeling diode (FWD) is provided, and is used in an inverter device and the like.

In this type of semiconductor module, a semiconductor element is arranged on an insulating substrate (which may be referred to as a stacked substrate), and a metal wiring board for wiring (which may be referred to as a lead frame) is arranged on an upper surface electrode of the semiconductor element in, for example, Patent Literatures 1 to 3. The metal wiring board is formed into a predetermined shape by, for example, pressing a metal plate. One end of the metal wiring board is electrically bonded to the upper surface electrode with a bonding material such as solder.

In the semiconductor module, a sealing resin is filled in a case member, and an internal structure including the metal wiring board is covered with the sealing resin. In order to improve the adhesion strength of the sealing resin to the metal wiring board, Patent Literature 4 describes that a dovetail-shaped groove having a narrower open portion than the width of a bottom portion is formed in the metal wiring board, and Patent Literature 5 describes that a plurality of lattice-shaped grooves are formed in the metal wiring board.

Patent Literatures 6 to 9 describe that a plurality of dimples are formed on a surface of the metal wiring board and protrusions (bending portions, turnover portions, hook portions) are provided on inner walls of the dimples to improve the adhesion strength of the sealing resin. As a method of forming the dimples, holes are formed by the first pressing, and some of the holes are deformed to form the protrusions on the inner walls by performing the second pressing on peripheries of the holes.

### CITATION LIST

### Patent Literature

Patent Literature 1: JP 2018-088448 A
Patent Literature 2: JP 2016-139635 A
Patent Literature 3: JP 2015-176871 A
Patent Literature 4: JP 6-163773 A
Patent Literature 5: JP 2021-077718 A
Patent Literature 6: JP 7-273270 A
Patent Literature 7: JP 2005-191178 A
Patent Literature 8: JP 2017-005124 A
Patent Literature 9: JP 2007-258587 A

### SUMMARY OF INVENTION

### Technical Problem

In this type of semiconductor module, the power semiconductor element generates heat following a switching operation. In the structure in which the metal wiring board is solder-bonded to the surface of the power semiconductor element as described above, distortion may occur in the bonding portion due to a fluctuation of internal stress generated with temperature change. As a result, a decrease in the adhesion of the sealing resin to the bonding portion of the metal wiring board is assumed.

The present invention has been made in view of such a point, and an object of the present invention is to provide a semiconductor module capable of improving adhesion between a bonding portion of a metal wiring board and a sealing resin.

### Solution to Problem

The semiconductor module according to one aspect of the present invention includes: a stacked substrate in which a plurality of circuit boards are arranged on an upper surface of an insulating plate; a semiconductor element arranged on an upper surface of at least one of the circuit boards; and a metal wiring board arranged on an upper surface of the semiconductor element, in which the metal wiring board has a plate-shaped bonding portion bonded to the upper surface of the semiconductor element via a bonding material, and a plurality of roughened recessed portions that roughen an upper surface of the bonding portion are provided, each of the plurality of roughened recessed portions having a hexagonal shape in plan view.

### Advantageous Effects of Invention

According to the present invention, adhesion between a bonding portion of a metal wiring board and a sealing resin in a semiconductor module can be improved.

### BRIEF DESCRIPTION OF DRAWINGS

FIG. 1 is a schematic view of a semiconductor device according to a present embodiment as viewed from above.

FIG. 2 is a cross-sectional view of the semiconductor device illustrated in FIG. 1 taken along line A-A.

FIG. 3 is an enlarged view of a metal wiring board according to the present embodiment.

FIG. 4 is a plan view illustrating a specific example of a semiconductor module to which the metal wiring board according to the present embodiment is applied.

FIG. 5 is an equivalent circuit diagram of the semiconductor device according to the present embodiment.

FIG. 6 is a plan view of a first bonding portion of the metal wiring board illustrated in FIG. 3 as viewed in a direction of arrow B.

FIG. 7 is a cross-sectional view taken along line C-C in FIG. 6.

FIG. 8 is an enlarged view of a portion D in FIG. 6.

FIG. 9 is an enlarged view of the portion D in FIG. 6.

FIG. 10 is a plan view illustrating a first modification example of roughened recessed portions provided in a first bonding portion of the metal wiring board.

FIG. 11 is a plan view illustrating a second modification example of the roughened recessed portions provided in the first bonding portion of the metal wiring board.

### DESCRIPTION OF EMBODIMENTS

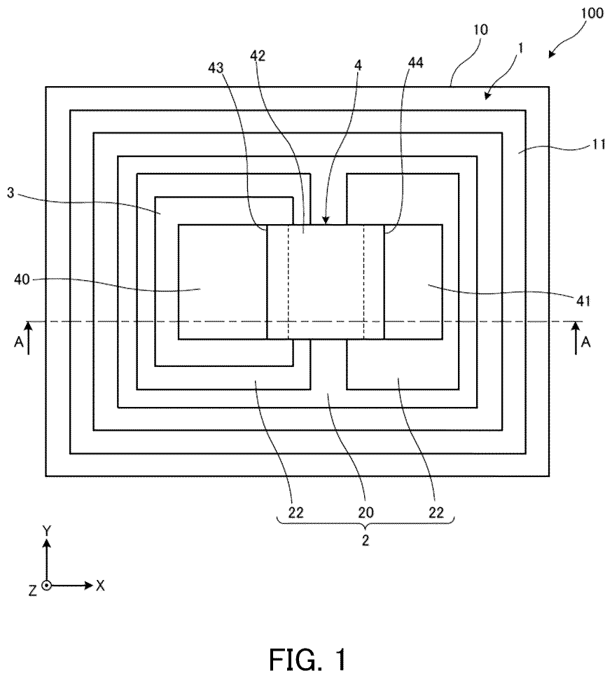

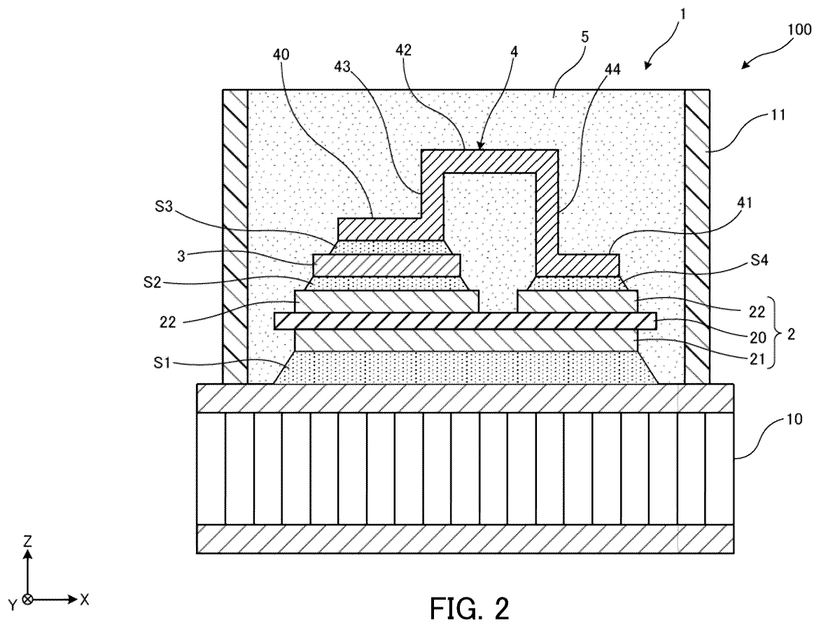

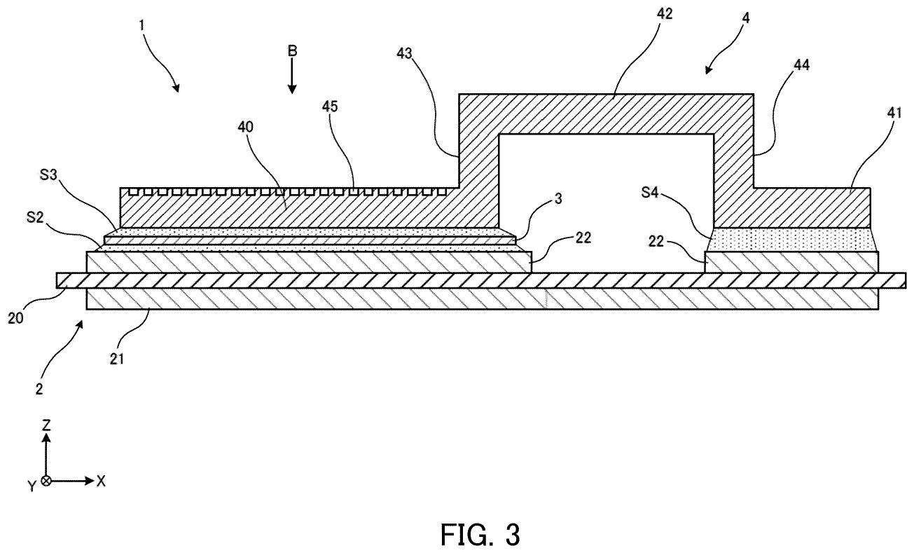

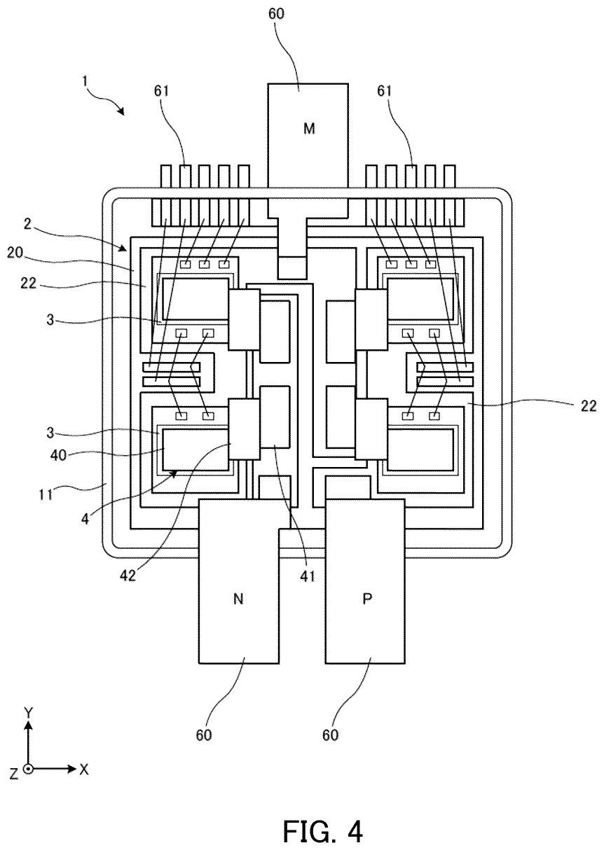

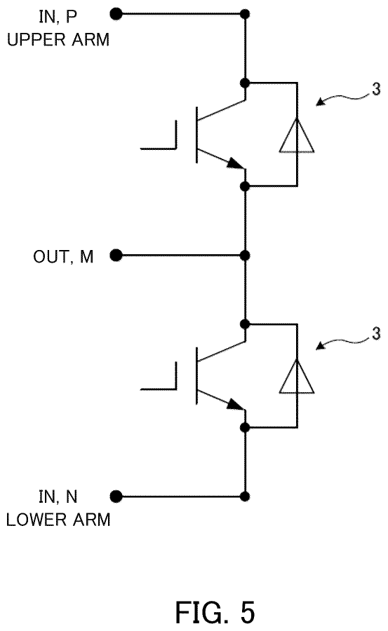

Hereinafter, a semiconductor module and a semiconductor device to which the present invention can be applied will be described. First, referring to FIGS. 1 to 5, the entirety of a semiconductor module and a semiconductor device and a schematic configuration of a metal wiring board including the semiconductor module and the semiconductor device will be described. FIG. 1 is a schematic view of a semiconductor device according to a present embodiment as viewed from above. FIG. 2 is a cross-sectional view of the semiconductor device illustrated in FIG. 1 taken along line A-A. FIG. 3 is an enlarged view of a metal wiring board according to the present embodiment. FIG. 4 is a plan view illustrating a specific example of a semiconductor module to which the metal wiring board according to the present embodiment is applied. FIG. 5 is an equivalent circuit diagram of the semiconductor device according to the present embodiment. Here, the configuration is such that anti-parallel circuits of an IGBT and an FWD are connected in series as a semiconductor element 3.

In the following drawings, a longitudinal direction of the semiconductor module (a cooler) is defined as an X direction, a lateral direction of the semiconductor module (the cooler) is defined as a Y direction, and a height direction (a direction of the thickness of the substrate) is defined as a Z direction. The longitudinal direction of the semiconductor module indicates a direction in which the plurality of circuit boards are arrayed. X, Y, and Z axes illustrated are orthogonal to each other and form a right-handed system. In some cases, the X direction may be referred to as a left-right direction, the Y direction may be referred to as a front-rear direction, and the Z direction may be referred to as an up-down direction. These directions (front-rear, left-right, and up-down directions) are terms used for convenience of description, and a correspondence relationship with the XYZ directions, respectively, may change depending on an attachment posture of the semiconductor module. For example, a heat dissipation surface side (cooler side) of the semiconductor module is referred to as a lower surface side, and the opposite side is referred to as an upper surface side. Also, in the present specification, the term “in plan view” means a case where an upper surface or a lower surface of the semiconductor module is viewed in the Z direction. In addition, the ratio between the width and the thickness and the size relationship between the members in the drawings are illustrated in schematic views, and thus are not necessarily the same among the drawings. For convenience of description, it is also assumed that the size relationship between the members may be exaggerated.

A semiconductor device 100 according to the present embodiment is applied to, for example, a power conversion device such as an inverter of an industrial or in-vehicle motor. As illustrated in FIGS. 1 and 2, the semiconductor device 100 is configured by arranging a semiconductor module 1 on an upper surface of a cooler 10. Note that the cooler 10 has any configuration with respect to the semiconductor module 1.

The cooler 10 releases heat of the semiconductor module 1 to the outside, and has a rectangular parallelepiped shape as a whole. Although not particularly illustrated, the cooler 10 is configured by providing a plurality of fins on a lower surface side of a base plate and housing these fins in a water jacket. Note that the cooler 10 is not limited thereto and can be appropriately changed.

The semiconductor module 1 is configured by arranging a stacked substrate 2, the semiconductor element 3, a metal wiring board 4, and the like in a case 11.

The stacked substrate 2 is composed of, for example, a direct copper bonding (DCB) substrate, an active metal brazing (AMB) substrate, or a metal base substrate. The stacked substrate 2 is configured by stacking an insulating plate 20, a heat dissipation plate 21, and a plurality of circuit boards 22, and is formed into a rectangular shape as a whole in plan view.

Specifically, the insulating plate 20 is formed from a plate-shaped body having an upper surface and a lower surface, and has a rectangular shape elongated in the X direction in plan view. The insulating plate 20 may be formed from, for example, a ceramic material such as aluminum oxide (Al₂O₃), aluminum nitride (AlN), silicon nitride (Si₃N₄), and aluminum oxide (Al₂O₃) and zirconium oxide (ZrO₂).

In addition, the insulating plate 20 may be formed from, for example, a thermosetting resin such as an epoxy resin or a polyimide resin, or a composite material using glass or a ceramic material as a filler in the thermosetting resin. The insulating plate 20 preferably has flexibility and may be formed from, for example, a material containing a thermosetting resin. Further, the insulating plate 20 may be referred to as an insulating layer or an insulating film.

The heat dissipation plate 21 has a predetermined thickness in the Z direction and has a rectangular shape elongated in the Y direction in plan view. The heat dissipation plate 21 is formed from, for example, a metal plate having good thermal conductivity such as copper or aluminum. The heat dissipation plate 21 is arranged on a lower surface of the insulating plate 20. The lower surface of the heat dissipation plate 21 is a surface to be attached to the cooler 10, a device to which the semiconductor module 1 is attached, and also functions as a heat dissipation surface (heat dissipation region) for releasing heat of the semiconductor module 1. The heat dissipation plate 21 is bonded to the upper surface of the cooler 10 via a bonding material S1 such as solder. The heat dissipation plate 21 may be arranged on the upper surface of the cooler 10 with a thermal conductive material, such as thermal grease or thermal compound, interposed therebetween.

Each of the plurality of circuit boards 22 has a predetermined thickness and is arranged on the upper surface of the insulating plate 20. Each of the circuit boards 22 is formed into an electrically independent island shape. For example, the circuit board 22 has a rectangular shape in plan view, and is arranged side by side in the X direction on the insulating plate 20. Note that the number of the circuit boards 22 is not limited to two as illustrated in FIG. 1, and can be changed as appropriate. As illustrated in FIG. 4, three or more circuit boards 22 may be arranged on the insulating plate 20. In addition, the shape, arrangement location, and the like of the circuit board 22 are not limited thereto and can be changed as appropriate. These circuit boards 22 are formed from, for example, a metal plate having good thermal conductivity such as copper or aluminum. The circuit board 22 may be referred to as a circuit layer or a circuit pattern.

The semiconductor element 3 is arranged on an upper surface of the predetermined circuit board 22 (circuit board 22 on the negative side in the X direction) via a bonding material S2 such as solder. The semiconductor element 3 is formed from a semiconductor substrate such as silicon (Si) or silicon carbide (SiC) in a rectangular shape in plan view. The semiconductor element 3 may be a power semiconductor element. For the semiconductor element 3, a switching element such as an insulated gate bipolar transistor (IGBT) and a power metal oxide semiconductor field effect transistor (power MOSFET), and a diode such as a free wheeling diode (FWD) are used.

In the present embodiment, the semiconductor element 3 includes, for example, a reverse conducting (RC)-insulated gate bipolar transistor (IGBT) element in which the functions of an IGBT element and a free wheeling diode (FWD) element are integrated.

Note that the semiconductor element 3 is not limited thereto, and may be configured by combining the above-described switching element, diode, and the like. For example, the IGBT element and the FWD element may be configured separately. Also, a reverse blocking (RB)-IGBT or the like having a sufficient withstand voltage against a reverse bias may be used as the semiconductor element 3. In addition, the shape, number, arrangement location, and the like of the semiconductor element 3 can appropriately be changed.

In addition, electrodes (not illustrated) are formed on an upper surface and a lower surface of the semiconductor element 3, respectively. For example, the electrode on the upper surface side (upper surface electrode) is configured as an emitter electrode (source electrode) or a gate electrode, and the electrode on the lower surface side (lower surface electrode) is configured as a collector electrode (drain electrode).

Note that the semiconductor element 3 in the present embodiment is a so-called vertical switching element in which the functional element as described above is formed on a semiconductor substrate, but is not limited thereto, and may be a horizontal switching element.

The metal wiring board 4 is arranged on the upper surface of the semiconductor element 3. The metal wiring board 4 is configured as a plate-shaped body having an upper surface and a lower surface, and is formed from, for example, a metal material such as a copper material, a copper alloy-based material, an aluminum alloy-based material, or an iron alloy-based material. The metal wiring board 4 is formed into a predetermined shape by, for example, pressing. Note that the shape of the metal wiring board 4 described below is merely an example, and can be changed as appropriate. In addition, the metal wiring board may be referred to as a lead frame.

The metal wiring board 4 according to the present embodiment is an elongated body extending in the X direction so as to straddle the plurality of circuit boards 22 in plan view, and has a crank shape that is bent a plurality of times in side view. Specifically, as illustrated in FIGS. 2 and 3, the metal wiring board 4 is configured by including a first bonding portion 40 bonded to the upper surface (the upper surface electrode) of the semiconductor element 3 via a bonding material S3 (a first bonding material), a second bonding portion 41 bonded to the upper surface of the circuit board 22 on the positive side in the X direction via a bonding material S4, and a connecting portion 42 connecting the first bonding portion 40 and the second bonding portion 41.

The width of the metal wiring board 4 in the Y direction is uniform from the first bonding portion 40 to the second bonding portion 41. In addition, the first bonding portion 40, the second bonding portion 41, and the connecting portion 42 are arranged in a line along the X direction in plan view. Note that the width of the metal wiring board 4 in the Y direction is not necessarily uniform from the first bonding portion 40 to the second bonding portion 41, and each portion may have a different width as illustrated in FIG. 4. In addition, the first bonding portion 40, the second bonding portion 41, and the connecting portion 42 are not necessarily arranged in a line, and may be arranged to be obliquely shifted from each other as illustrated in FIG. 4.

The first bonding portion 40 is formed into a rectangular shape smaller than the outer shape of the semiconductor element 3 in plan view, and includes a plate-shaped portion having an upper surface and a lower surface. A first bent portion 43 that is bent at a substantially right angle and rises upward is formed at an end portion of the first bonding portion 40 on the positive side in the X direction (the connecting portion 42 side). One end (the left end) of the connecting portion 42 is connected to the upper end of the first bent portion 43.

The second bonding portion 41 is formed into a rectangular shape smaller than the outer shape of the circuit board 22 in plan view, and includes a plate-shaped portion having an upper surface and a lower surface. A second bent portion 44 that is bent at a substantially right angle and rises upward is formed at an end portion of the second bonding portion 41 on the negative side in the X direction (the connecting portion 42 side). The other end (the right end) of the connecting portion 42 is connected to the upper end of the second bent portion 44.

The connecting portion 42 extends in the horizontal direction, and as described above, one end thereof is connected to the first bent portion 43 and the other end thereof is connected to the second bent portion 44.

The length of the first bent portion 43 in the Z direction is shorter than that of the second bent portion 44 by the thickness of the semiconductor element 3. That is, the first bonding portion 40 and the second bonding portion 41 are provided at a position with different heights. More specifically, the first bonding portion 40 is provided at a position higher than the second bonding portion 41.

Note that the shape, number, arrangement location, and the like of the metal wiring board 4 described above are merely examples, and are not limited thereto and can be changed as appropriate. Although details will be described later, a plurality of (for example, four) metal wiring boards 4 may be arranged on one semiconductor module as illustrated in FIG. 4. In the present embodiment, the semiconductor element 3 and the metal wiring board 4 described above, and a main terminal and the like to be described later form, for example, an inverter circuit illustrated in FIG. 5.

The periphery of the stacked substrate 2, the semiconductor element 3, and the metal wiring board 4 is surrounded by the case 11. The case 11 has a quadrangular annular tubular shape or a frame shape in plan view, and is formed from, for example, a synthetic resin. The case 11 may be formed from, for example, a thermosetting resin material such as an epoxy resin or silicone rubber. The lower end of the case 11 is adhered to the upper surface of the cooler 10 with an adhesive (not illustrated), and the upper end extends to a position sufficiently higher than the upper surface of the metal wiring board 4. Thus, the case 11 surrounds the periphery of the stacked substrate 2, the semiconductor element 3, and the metal wiring board 4, and defines a space for housing the stacked substrate 2, the semiconductor element 3, and the metal wiring board 4.

The internal space defined by the case 11 is filled with a sealing resin 5. The case 11 may be filled with the sealing resin 5 until its upper surface reaches the upper end of the case 11. Thus, the stacked substrate 2, the semiconductor element 3, and the metal wiring board 4 are sealed. The entire metal wiring board 4 is covered with the sealing resin 5.

The sealing resin 5 may be composed of, for example, a thermosetting resin. Preferably, the sealing resin 5 contains at least one of epoxy, silicone, urethane, polyimide, polyamide, and polyamide-imide. For example, an epoxy resin mixed with a filler is suitable for the sealing resin 5 from the viewpoint of insulation, heat resistance, and heat dissipation properties.

Also, as in the specific example illustrated in FIG. 4, the case 11 may be provided with a plurality of main terminals 60 for main current and a plurality of control terminals 61 for control. The main terminal 60 is formed into a plate-shaped elongated body and is embedded in a side wall of the case 11. In FIG. 4, two main terminals 60 constituting an N terminal and a P terminal, respectively, are arranged side by side in the X direction on the side wall of the case 11 positioned on the negative side in the Y direction. In addition, a main terminal 60 constituting an M terminal is arranged on the side wall of the case 11 positioned on the positive side in the Y direction.

As described above, in the present embodiment, the semiconductor element 3, the metal wiring board 4, the main terminals 60, and the like form, for example, the inverter circuit illustrated in FIG. 5. These main terminals 60 (the N terminal, P terminal, M terminal) correspond to IN (N) (which may be referred to as a low potential-side input terminal or a negative electrode terminal), IN (P) (which may be referred to as a high potential-side input terminal or a positive electrode terminal), and OUT (M) (which may be referred to as an output terminal or an intermediate terminal) in FIG. 5, respectively.

In addition, the control terminal 61 is formed into a plate-shaped elongated body and is embedded in the side wall of the case 11 positioned on the positive side in the Y direction. The control terminal 61 is electrically connected to a predetermined control electrode of the semiconductor element 3 via a wiring member such as a bonding wire. These main terminal 60 and the control terminal 61 are formed from a metal material such as a copper material, a copper alloy-based material, an aluminum alloy-based material, or an iron alloy-based material, and have predetermined electrical conductivity and predetermined mechanical strength. The shapes, numbers, arrangement locations, and the like of the main terminal 60 and the control terminal 61 are not limited thereto, and can be changed as appropriate.

Incidentally, in the semiconductor module, it is desired to prevent the progress of peeling along the interface between the metal wiring board and the sealing resin. As a method for reducing peeling, it is conceivable, for example, to increase the surface area of the metal wiring board to improve adhesion (anchor effect) between the metal wiring board and the sealing resin. Examples of a method for increasing the surface area of the metal wiring board include forming an uneven shape on the surface of the metal wiring board to roughen the surface.

In the present embodiment, in a configuration of providing roughened recessed portions on the upper surface of the metal wiring board to roughen the upper surface, the arrangement density a plurality of roughened recessed portions is increased, the progress of peeling of the sealing resin from the metal wiring board is suppressed, and the anchor effect is improved as compared to the structure in the related art.

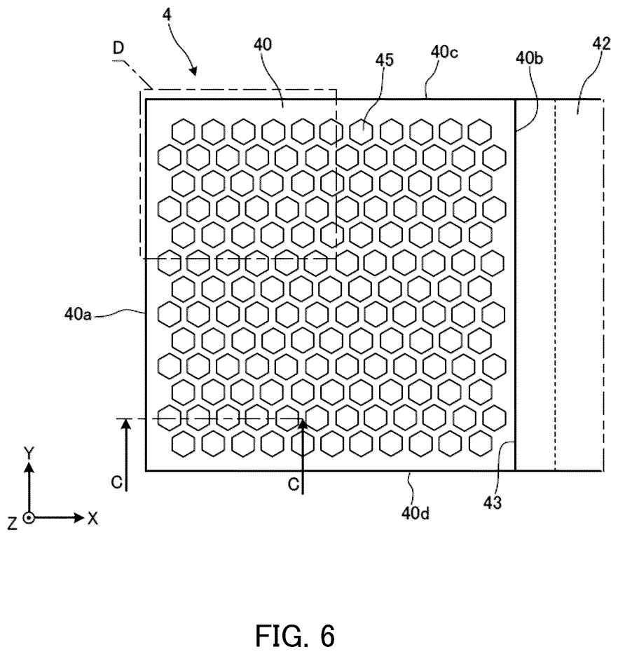

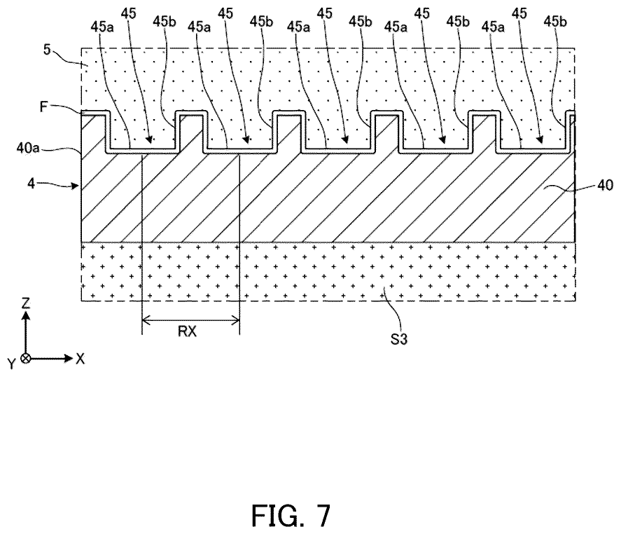

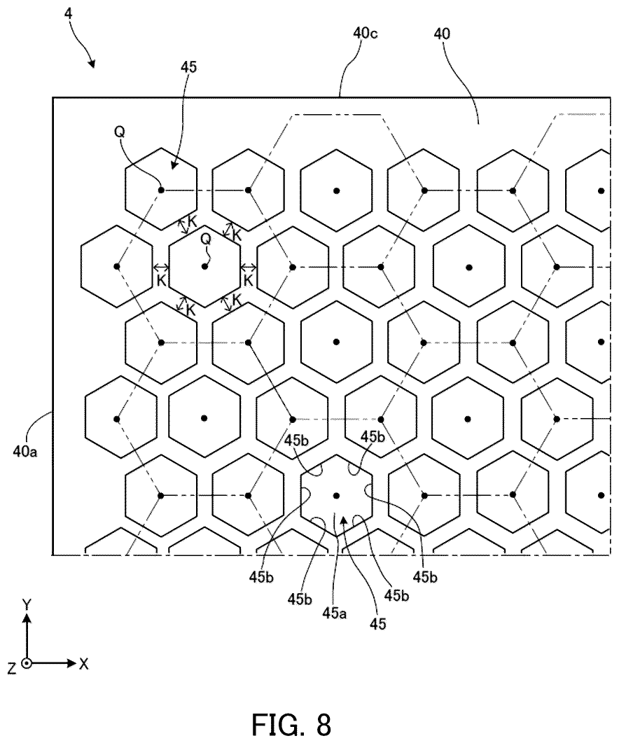

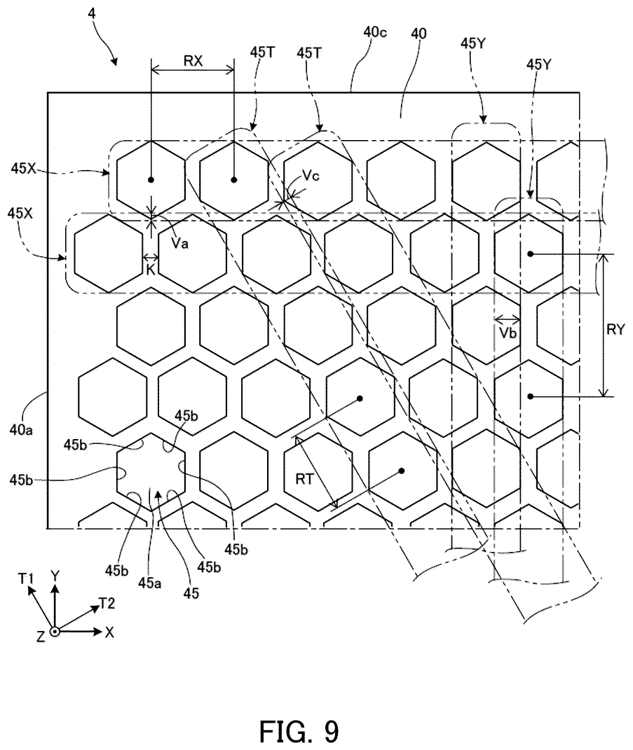

Specifically, the present embodiment aims to roughen the upper surface of the first bonding portion 40 of the metal wiring board 4 constituting the semiconductor module 1. FIG. 6 is a plan view of the first bonding portion 40 of the metal wiring board 4 illustrated in FIG. 3 as viewed in a direction of arrow B. FIG. 7 is a cross-sectional view taken along line C-C in FIG. 6. FIGS. 8 and 9 are enlarged views of a portion D in FIG. 6.

As illustrated in FIG. 6, the first bonding portion 40 having a rectangular shape in plan view includes a tip outer edge 40a on a tip side in the X direction (end portion opposite to the connecting portion 42) and includes a boundary portion 40b that is a boundary between the first bent portion 43 and an end portion opposite to the tip outer edge 40a in the X direction. Each of the tip outer edge 40a and the boundary portion 40b has a linear shape extending in the Y direction. In addition, the first bonding portion 40 includes a pair of a lateral outer edge 40c and a lateral outer edge 40d that connect opposite ends of the tip outer edge 40a and the boundary portion 40b extending in the X direction. The tip outer edge 40a, the boundary portion 40b, the lateral outer edge 40c, and the lateral outer edge 40d constitute the outer edge of the first bonding portion 40 having a rectangular shape in plan view.

As illustrated in FIG. 6, a plurality of roughened recessed portions 45 are roughened on the upper surface of the first bonding portion 40 to roughen the upper surface. Each of the roughened recessed portions 45 has a hexagonal shape in plan view. The peeling at the interface between the first bonding portion 40 and the sealing resin 5 is likely to occur in the end portion (outer edge) of the first bonding portion 40. Although details described below, the roughened recessed portions 45 having a hexagonal shape are likely to be arranged with high density, and by uniformly providing the roughened recessed portions 45 on the upper surface of the first bonding portion 40, the progress of peeling occurring in the end portion of the first bonding portion 40 toward the inner region of the first bonding portion 40 can be suppressed.

As illustrated in FIG. 7, each of the roughened recessed portions 45 includes a bottom surface 45a at one end (lower side) in the Z direction and includes a bottomed recessed portion that is opened to the upper surface of the first bonding portion 40 at the other end (upper side) in the Z direction. The bottom surface 45a has a regular hexagonal shape and includes six inner wall surfaces 45b which extend in the Z direction from six sides of the bottom surface 45a, respectively. That is, each of the roughened recessed portions 45 has a hexagonal cylindrical shape surrounded by the bottom surface 45a and the six inner wall surfaces 45b. All of the plurality of roughened recessed portions 45 have the same shape, size, and depth. In addition, as illustrated in FIG. 7, a coating film F may be interposed at the interface between the upper surface of the first bonding portion 40 and the sealing resin 5.

By providing the plurality of roughened recessed portions 45, the upper surface of the first bonding portion 40 is roughened to increase the surface area, and the adhesion (anchor effect) between the upper surface of the first bonding portion 40 and the sealing resin 5 is improved. In addition, as illustrated in FIG. 7, it is preferable that the sealing resin 5 enters the roughened recessed portions 45. As a result, a further anchor effect can be expected. Accordingly, the progress of the peeling of the sealing resin 5 on the upper surface of the metal wiring board 4 due to thermal stress can be suppressed at a position above the semiconductor element 3.

The arrangement of the plurality of roughened recessed portions 45 will be described in detail. As illustrated in FIG. 8, the plurality of roughened recessed portions 45 are arranged in the same direction such that centers thereof are positioned at lattice points Q of a hexagonal lattice (regular triangular lattice) in plan view. Accordingly, the two roughened recessed portions 45 having an adjacent positional relationship are arranged such that the inner wall surfaces 45b most adjacent to each other are parallel to each other. A predetermined interval K is present between the two roughened recessed portions 45 adjacent to each other (between the inner wall surfaces 45b most adjacent to each other). The plurality of roughened recessed portions 45 are arranged at regular intervals on the entire upper surface of the first bonding portion 40 such that the intervals K are equal.

By applying the roughened recessed portions 45 having a hexagonal shape in plan view, the roughened recessed portions 45 can be arranged on the upper surface of the first bonding portion 40 with high density. Specifically, by arranging the plurality of roughened recessed portions 45 in the same direction such that the centers of the roughened recessed portions 45 are positioned on the lattice points Q of the hexagonal lattice in plan view, the intervals K between the roughened recessed portions 45 can be narrowed, and many roughened recessed portions 45 can be formed on the upper surface of the first bonding portion 40 with high spatial efficiency. Accordingly, the anchor effect by surface roughening can be further improved as compared to a case where roughened recessed portions having a rectangular shape or the like in plan view are used.

In addition, in the present embodiment, the arrangement density of the roughened recessed portions 45 is high, and the effect of preventing the progress of the peeling of the sealing resin 5 from the metal wiring board 4 is also excellent due to the reason described below.

A plurality of roughened recessed portion arrays including the plurality of roughened recessed portions 45 arrayed at intervals in a first direction are provided on the upper surface of the first bonding portion 40. The first direction is a direction in which any straight line parallel to the upper surface of the first bonding portion 40 extends. Meanwhile, the two adjacent roughened recessed portion arrays are arranged such that positions of the roughened recessed portions 45 are shifted from each other in the first direction, and have a region (overlapping region) where some of the roughened recessed portions 45 overlap each other in a second direction orthogonal to the first direction.

Referring to FIG. 9, the roughened recessed portion arrays and the overlapping region will be described. For example, it is assumed that the X direction is the first direction and the Y direction is the second direction. The plurality of roughened recessed portions 45 arrayed at intervals (intervals K) in the X direction are assumed as roughened recessed portion arrays 45X. In FIG. 9, a series of the roughened recessed portions 45 in each of the roughened recessed portion arrays 45X is surrounded by a frame of a two-dot chain line. In the roughened recessed portion array 45X, intervals of the centers of the roughened recessed portions 45 arrayed in the X direction are assumed as pitches RX.

As illustrated in FIG. 9, two roughened recessed portion arrays 45X adjacent to each other in the Y direction are arranged such that positions of the roughened recessed portions 45 are shifted from each other in the X direction. More specifically, in two roughened recessed portion arrays 45X adjacent to each other in the Y direction, the roughened recessed portions 45 are alternately arranged such that positions thereof are shifted from each other at half of the distances of the pitches RX (half pitches) in the X direction. As a result, the two adjacent roughened recessed portion arrays 45X can be approximated to each other in the Y direction. Meanwhile, the two adjacent roughened recessed portion arrays 45X are approximated to each other in the Y direction and arranged such that one roughened recessed portion 45 in one roughened recessed portion array 45X is interposed between two roughened recessed portions 45 in the other roughened recessed portion array 45X. As a result, the two roughened recessed portion arrays 45X adjacent to each other in the Y direction have an overlapping region Va where some of the roughened recessed portions 45 are alternately present in an intermediate region in the Y direction. The overlapping region Va is an elongated region having a predetermined width in the Y direction and extending in the X direction.

In the region where each of the roughened recessed portion arrays 45X is formed, the plurality of roughened recessed portions 45 are arrayed in the X direction. Therefore, the progress of peeling of the sealing resin 5 from the metal wiring board 4 in the X direction can be suppressed. In addition, the overlapping region Va is present between the two roughened recessed portion arrays 45X adjacent to each other in the Y direction, and some of the plurality of roughened recessed portions 45 in the two roughened recessed portion arrays 45X are alternately arranged in the overlapping region Va. Therefore, the progress of peeling of the sealing resin 5 from the metal wiring board 4 in the X direction can be suppressed. Accordingly, in the roughening target range of the upper surface of the first bonding portion 40, the roughened recessed portions 45 are always arranged on a freely set straight line extending in the X direction such that locations that are non-roughened regions (regions where the roughened recessed portions 45 are not formed) are not present in the entire region in the X direction.

Next, a case where the Y direction is a first direction and the X direction is a second direction will be described. The plurality of roughened recessed portions 45 arrayed at intervals in the Y direction are assumed as roughened recessed portion arrays 45Y. In FIG. 9, a series of the roughened recessed portions 45 in each of the roughened recessed portion arrays 45Y is surrounded by a frame of a two-dot chain line. In the roughened recessed portion array 45Y, intervals of the centers of the roughened recessed portions 45 arrayed in the Y direction are assumed as pitches RY.

In two roughened recessed portion arrays 45Y adjacent to each other in the X direction, the roughened recessed portions 45 are alternately arranged such that positions thereof are shifted from each other at half of the pitches RY (half pitches) in the Y direction. As a result, the two adjacent roughened recessed portion arrays 45Y can be approximated to each other in the X direction. Meanwhile, the two adjacent roughened recessed portion arrays 45Y are approximated to each other in the X direction and arranged such that one roughened recessed portion 45 in one roughened recessed portion array 45Y is interposed between two roughened recessed portions 45 in the other roughened recessed portion array 45Y. As a result, the two roughened recessed portion arrays 45Y adjacent to each other in the X direction have an overlapping region Vb where some of the roughened recessed portions 45 are alternately present in an intermediate region in the X direction. The overlapping region Vb is an elongated region having a predetermined width in the X direction and extending in the Y direction.

In the region where each of the roughened recessed portion arrays 45Y is formed, the plurality of roughened recessed portions 45 are arrayed in the Y direction. Therefore, the progress of peeling of the sealing resin 5 from the metal wiring board 4 in the Y direction can be suppressed. In addition, the overlapping region Vb is present between the two roughened recessed portion arrays 45Y adjacent to each other in the X direction, and some of the plurality of roughened recessed portions 45 in the two roughened recessed portion arrays 45Y are alternately arranged in the overlapping region Vb. Therefore, the progress of peeling of the sealing resin 5 from the metal wiring board 4 in the Y direction can be suppressed. Accordingly, in the roughening target range of the upper surface of the first bonding portion 40, the roughened recessed portions 45 are always arranged on a freely set straight line extending in the Y direction such that locations that are non-roughened regions (regions where the roughened recessed portions 45 are not formed) are not present in the entire region in the Y direction.

Further, in the present embodiment, the roughened recessed portions 45 are always arranged not only on any straight line extending in the X direction and any straight line extending in the Y direction but also on any straight line extending in a direction (oblique direction) intersecting the X direction and the Y direction such that locations that are non-roughened regions (regions where the roughened recessed portions 45 are not formed) are not present in the entire region in the oblique direction.

For example, FIG. 9 illustrates an oblique direction T1 as an example of the oblique direction. In addition, a direction orthogonal to the oblique direction T1 is assumed as an orthogonal direction T2. The oblique direction T1 is a direction inclined by) 60° (120° with respect to the X direction and inclined by) 30° (150° with respect to the Y direction. A case where the oblique direction T1 is the first direction and the orthogonal direction T2 is the second direction will be described. The plurality of roughened recessed portions 45 arrayed at intervals in the oblique direction T1 are assumed as roughened recessed portion arrays 45T. In FIG. 9, a series of the roughened recessed portions 45 in each of the roughened recessed portion arrays 45T is surrounded by a frame of a two-dot chain line. In the roughened recessed portion array 45T, intervals of the centers of the roughened recessed portions 45 arrayed in the oblique direction T1 are assumed as pitches RT.

In two roughened recessed portion arrays 45T adjacent to each other in the orthogonal direction T2, the roughened recessed portions 45 are alternately arranged such that positions thereof are shifted from each other at half of the pitches RT (half pitches) in the oblique direction T1. As a result, the two adjacent roughened recessed portion arrays 45T can be approximated to each other in the orthogonal direction T2. Meanwhile, the two adjacent roughened recessed portion arrays 45T are approximated to each other in the orthogonal direction T2 and arranged such that one roughened recessed portion 45 in one roughened recessed portion array 45T is interposed between two roughened recessed portions 45 in the other roughened recessed portion array 45T. As a result, the two roughened recessed portion arrays 45T adjacent to each other in the orthogonal direction T2 have an overlapping region Vc where some of the roughened recessed portions 45 are alternately present in an intermediate region in the orthogonal direction T2. The overlapping region Vc is an elongated region having a predetermined width in the orthogonal direction T2 and extending in the oblique direction T1.

In the region where each of the roughened recessed portion arrays 45T is formed, the plurality of roughened recessed portions 45 are arrayed in the oblique direction T1. Therefore, the progress of peeling of the sealing resin 5 from the metal wiring board 4 in the oblique direction T1 can be suppressed. In addition, the overlapping region Vc is present between the two roughened recessed portion arrays 45T adjacent to each other in the orthogonal direction T2, and some of the plurality of roughened recessed portions 45 in the two roughened recessed portion arrays 45T are alternately arranged in the overlapping region Vc. Therefore, the progress of peeling of the sealing resin 5 from the metal wiring board 4 in the oblique direction T1 can be suppressed. Accordingly, in the roughening target range of the upper surface of the first bonding portion 40, the roughened recessed portions 45 are always arranged on a freely set straight line extending in the oblique direction T1 such that locations that are non-roughened regions (regions where the roughened recessed portions 45 are not formed) are not present in the entire region in the oblique direction T1.

FIG. 9 illustrates the X direction, the Y direction, and the oblique direction T1 as the direction (first direction) in which the non-roughened regions are not continuous on the upper surface of the first bonding portion 40. In the arrangement structure of the roughened recessed portions 45 according to the present embodiment, locations where the non-roughened regions are linearly continuous are not present in all of the directions in the roughening target range of the upper surface of the first bonding portion 40.

For example, although the details are not described, even when the orthogonal direction T2 of FIG. 9 is the first direction and the oblique direction T1 is the second direction, the above-described condition (the overlapping of the two adjacent roughened recessed portion arrays) is satisfied, and the above-described effects can be obtained. That is, in the roughening target range of the upper surface of the first bonding portion 40, the roughened recessed portions 45 are always arranged on a freely set straight line extending in the orthogonal direction T2 such that locations that are non-roughened regions (regions where the roughened recessed portions 45 are not formed) are not present in the entire region in the orthogonal direction T2.

Accordingly, when the peeling of the sealing resin 5 from the metal wiring board 4 occurs in the end portion (outer edge) of the first bonding portion 40, the roughened recessed portions 45 are present in any direction from the end portion toward the inside of the first bonding portion 40, and the effect of preventing the progress of peeling can be obtained.

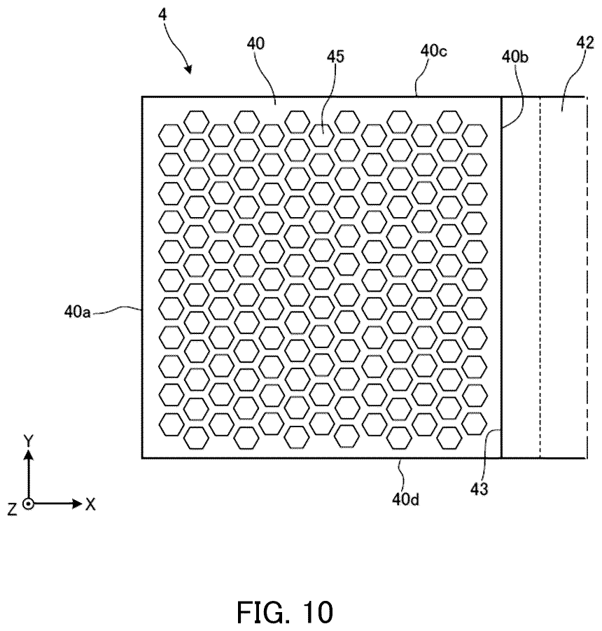

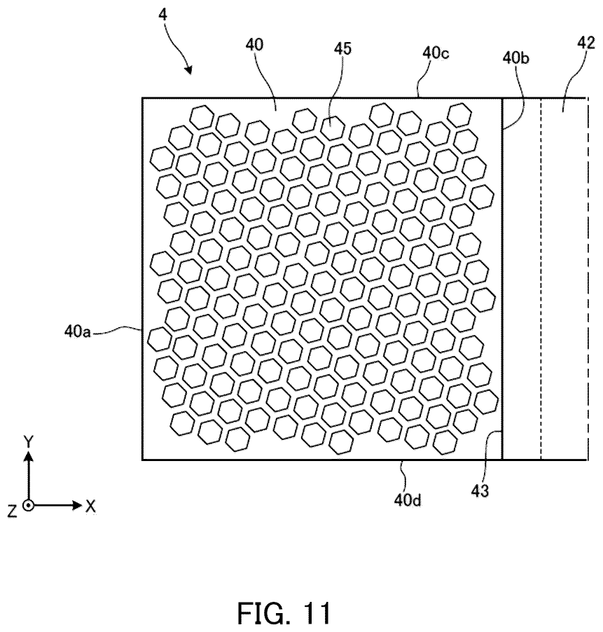

In the above-described embodiment of FIGS. 6 to 9, each of the roughened recessed portions 45 having a hexagonal shape in plan view is arranged in a direction in which two inner wall surfaces 45b among the six inner wall surfaces 45b are parallel to the Y direction. FIGS. 10 and 11 illustrate a modification example where the roughened recessed portions 45 are arranged in a direction different from the above-described direction.

In the first modification example of FIG. 10, each of the roughened recessed portions 45 having a hexagonal shape in plan view is arranged in a direction in which two of six inner wall surfaces 45b among the six inner wall surfaces 45b are parallel to the X direction. That is, in this arrangement, the direction of each of the roughened recessed portions 45 is rotated by 90° (270°) with respect to the direction of the roughened recessed portion 45 illustrated in FIG. 6.

In the second modification example illustrated in FIG. 11, each of the roughened recessed portions 45 having a hexagonal shape in plan view is arranged in a direction in which all the six inner wall surfaces 45b are not parallel to the X direction and the Y direction. Specifically, in this arrangement, the direction of each of the roughened recessed portions 45 is rotated by 45° (135°) with respect to the direction of the roughened recessed portion 45 illustrated in FIG. 6.

Both of the first modification example and the second modification example are common to the above-described embodiment, in that the plurality of roughened recessed portions 45 can be arranged on the upper surface of the first bonding portion 40 with high density and that locations where the non-roughened regions are linearly continuous are not present in the regions roughened by the plurality of roughened recessed portions 45 (the roughened recessed portions 45 are present on any straight line along the upper surface of the first bonding portion 40). Accordingly, the same effect as that of the above-described embodiment can be obtained.

In the second modification example illustrated in FIG. 11, all of the six inner wall surfaces 45b of the roughened recessed portion 45 are not parallel to the tip outer edge 40a, the boundary portion 40b, the lateral outer edge 40c, and the lateral outer edge 40d of the first bonding portion 40, and thus the arrangement density of the roughened recessed portions 45 slightly varies on the outer edge side of the first bonding portion 40.

On the other hand, in the above-described embodiment illustrated in FIG. 6, two of the six inner wall surfaces 45b of the roughened recessed portion 45 are parallel to the tip outer edge 40a and the boundary portion 40b of the first bonding portion 40, and the roughened recessed portions 45 are equally arranged at positions along the lateral outer edge 40c and the lateral outer edge 40d. In addition, in the first modification example illustrated in FIG. 10, two of the six inner wall surfaces 45b of the roughened recessed portion 45 are parallel to the lateral outer edge 40c and the lateral outer edge 40d of the first bonding portion 40, and the roughened recessed portions 45 are equally arranged at positions along the tip outer edge 40a and the boundary portion 40b.

Accordingly, when the first bonding portion 40 having a rectangular shape in plan view is to be roughened, in consideration of good arrangement efficiency of the roughened recessed portions 45 in the vicinity of the end portion (outer edge) of the first bonding portion 40, it is preferable that each of the plurality of roughened recessed portions 45 is arranged in a direction in which two of the six inner wall surfaces 45b are parallel to the end portion (outer edge) of the first bonding portion 40.

As described above, in the configurations of the present embodiment and the modification examples, a high effect of preventing the peeling of the sealing resin 5 on the upper surface of the first bonding portion 40 of the metal wiring board 4 can be obtained, and the adhesion between the metal wiring board 4 and the sealing resin 5 can be improved. Each of the plurality of roughened recessed portions 45 that roughen the upper surface of the first bonding portion 40 has a simple hexagonal shape in plan view, and thus there is an advantage in that the roughened recessed portions 45 can be easily formed on the metal wiring board 4 at a low cost. For example, the roughened recessed portions 45 can be formed by pressing the metal wiring board 4.

Since the semiconductor element 3 that is a heat source is arranged immediately below the first bonding portion 40, the first bonding portion 40 is largely affected by the anchor effect by surface roughening. Accordingly, it is desirable to provide the plurality of roughened recessed portions 45 on at least the upper surface of the first bonding portion 40 in the metal wiring board 4.

Regarding the portions of the metal wiring board 4 other than the first bonding portion 40, that is, the connecting portion 42, the first bent portion 43, and the second bent portion 44, the influence on the peeling of the sealing resin 5 is smaller than that in the first bonding portion 40, and thus whether to provide the roughened recessed portions 45 can be appropriately selected. For example, by roughening only the first bonding portion 40, the processing cost of the metal wiring board 4 can be reduced. In this case, the surfaces of the second bonding portion 41, the connecting portion 42, the first bent portion 43, and the second bent portion 44 are flat, and the surface roughness thereof may be equivalent to the surface roughness of the lower surface of the first bonding portion 40.

Also, in the above-described embodiment, the plurality of roughened recessed portions 45 are arranged at regular intervals on substantially the entire upper surface of the first bonding portion 40 of the metal wiring board 4. A part of the upper surface of the first bonding portion 40 may be the non-roughened region not including the roughened recessed portion 45. For example, when a wire is connected to the upper surface of the first bonding portion 40, a location to which the wire is to be connected may be the non-roughened region. In addition, a protrusion portion that protrudes upward from the metal wiring board 4, a through hole or the like that penetrates the upper surface and the lower surface of the metal wiring board 4, or the like can also be applied as the non-roughened region. In either case, the roughened recessed portions 45 can be provided with high density in the vicinity of the non-roughened region, and thus the above-described effect by the roughened recessed portions 45 can be obtained.

In the above-described embodiment, the plurality of roughened recessed portions 45 provided on the upper surface of the first bonding portion 40 have the same depth in the Z direction. By allowing the plurality of roughened recessed portions 45 to have the same depth, a process of the surface roughening can be easily performed as well as the shape accuracy of the first bonding portion 40 can be easily managed. However, the depths of the plurality of roughened recessed portion are not limited to this example, and a configuration where the roughened recessed portions having different depths are mixed can also be adopted.

In the above-described embodiment, all of the plurality of roughened recessed portions 45 provided on the upper surface of the first bonding portion 40 have the same size in plan view. However, the sizes of some of the roughened recessed portions can also be made different. For example, in the second modification example illustrated in FIG. 11, roughened recessed portions having a smaller area than the roughened recessed portions 45 in plan view may be arranged in regions in the vicinity of the outer edge along the tip outer edge 40a, the boundary portion 40b, the lateral outer edge 40c, and the lateral outer edge 40d of the first bonding portion 40. As a result, roughening can be efficiently performed up to the vicinity of the outer edge of the first bonding portion 40 while obtaining the above-described effect by the roughened recessed portions 45.

Although the present embodiment and the modification examples have been described above, the above-described embodiment and modification examples may be wholly or partially combined as another embodiment.

In the above-described embodiment, the number and arrangement location of the semiconductor element are not limited to the above-described configuration, and can appropriately be changed.

Furthermore, in the above-described embodiment, the number and layout of the circuit board are not limited to the above-described configuration, and can be changed as appropriate.

In the above-described embodiment, the stacked substrate or the semiconductor element has a rectangular shape or a square shape in a planar view, but the present invention is not limited to this configuration. These components may each have a polygonal shape other than the above-described shape.

In addition, the present embodiment is not limited to the above-described embodiment and modification examples, and various changes, substitutions, and modifications may be made without departing from the spirit of the technical idea. Further, when the technical idea can be realized in another manner by the progress of the technology or another derived technology, the technical idea may be carried out by using a method thereof. Accordingly, the claims cover all implementations that may be included within the scope of the technical idea.

Feature points in the embodiment described above will be summarized below.

The semiconductor module according to the above-described embodiment includes: a stacked substrate in which a plurality of circuit boards are arranged on an upper surface of an insulating plate; a semiconductor element arranged on an upper surface of at least one of the circuit boards; and a metal wiring board arranged on an upper surface of the semiconductor element, in which the metal wiring board has a plate-shaped bonding portion bonded to the upper surface of the semiconductor element via a bonding material, and a plurality of roughened recessed portions that roughen an upper surface of the bonding portion, each of the plurality of roughened recessed portions having a hexagonal shape in plan view.

In addition, the plurality of roughened recessed portions are arranged in the same direction such that centers of the roughened recessed portions are positioned at lattice points of a hexagonal lattice in plan view of the bonding portion.

In addition, a plurality of roughened recessed portion arrays including the plurality of roughened recessed portions arrayed at intervals in the first direction are provided on the upper surface of the bonding portion, and two of the roughened recessed portion arrays adjacent to each other are arranged such that positions of the roughened recessed portions are shifted from each other in the first direction, and have a region where some of the roughened recessed portions overlap each other in the second direction orthogonal to the first direction.

In addition, the bonding portion has a rectangular shape in plan view, and the first direction and the second direction include a direction parallel to an outer edge of the bonding portion and a direction intersecting the outer edge of the bonding portion.

In addition, the bonding portion has a rectangular shape in plan view, and each of the plurality of roughened recessed portions is arranged in a direction in which two of six inner wall surfaces forming a hexagonal shape in plan view are parallel to an outer edge of the bonding portion.

### INDUSTRIAL APPLICABILITY

As described above, the present invention has an effect of improving the adhesion between the bonding portion of the metal wiring board and the sealing resin and is particularly useful for a semiconductor module for industrial or electrical equipment.

The present application is based on Japanese Patent Application No. 2022-177079 filed on Nov. 4, 2022. All the contents are included herein.

### REFERENCE SIGNS LIST

1 Semiconductor module
2 Stacked substrate
3 Semiconductor element
4 Metal wiring board
5 Sealing resin
10 Cooler
11 Case
20 Insulating plate
21 Heat dissipation plate
22 Circuit board
40 First bonding portion (bonding portion)
40a Tip outer edge (outer edge)
40b Boundary portion (outer edge)
40c Lateral outer edge (outer edge)
40d Lateral outer edge (outer edge)
41 Second bonding portion
42 Connecting portion
43 First bent portion
44 Second bent portion
45 Roughened recessed portion
45a Bottom surface
45b Inner wall surface
45T Roughened recessed portion array
45X Roughened recessed portion array
45Y Roughened recessed portion array
60 Main terminal
61 Control terminal
100 Semiconductor device
F Coating film
S1 Bonding material
S2 Bonding material
S3 Bonding material
S4 Bonding material
T1 Oblique direction (first direction, second direction)
T2 Orthogonal direction (first direction, second direction)
Va Overlapping region
Vb Overlapping region
Vc Overlapping region
X X direction (first direction, second direction)
Y Y direction (first direction, second direction)

1. A semiconductor module comprising:
a stacked substrate, which includes:
an insulating plate, and
a plurality of circuit boards formed on an upper surface of the insulating plate;
a semiconductor element formed on an upper surface of one of the plurality of circuit boards; and
a metal wiring board formed on an upper surface of the semiconductor element, wherein
the metal wiring board has a plate-shaped bonding portion bonded to the upper surface of the semiconductor element via a bonding material, and
the plate-shaped bonding portion has a plurality of recessed portions formed on an upper surface thereof, each recessed portion is of a hexagonal shape in a plan view of the semiconductor module.

2. The semiconductor module according to claim 1, wherein the plurality of recessed portions are arranged in a same direction such that centers of the plurality of recessed portions are positioned at lattice points of a hexagonal lattice in the plan view.

3. The semiconductor module according to claim 2, wherein
the plurality of recessed portions are arranged in a plurality of arrays each extending in a first direction, and
the plurality of arrays are so arranged that
positions of the recessed portions in adjacent two of the arrays are shifted from each other in the first direction, and
at least two of the recessed portions overlap each other in a second direction orthogonal to the first direction.

4. The semiconductor module according to claim 3, wherein
the bonding portion has a rectangular shape in the plan view, and
either the first direction or the second direction is parallel to an outer edge of the bonding portion.

5. The semiconductor module according to claim 2, wherein
the bonding portion has a rectangular shape in the plan view, and
each of the plurality of recessed portions is so arranged that two of six inner wall surfaces forming the hexagonal shape thereof in the plan view are parallel to an outer edge of the bonding portion.

6. The semiconductor module according to claim 1, wherein
the plurality of recessed portions are arranged in a plurality of arrays each extending in a first direction, and
the plurality of arrays are so arranged that
positions of the recessed portions in adjacent two of the arrays are shifted from each other in the first direction, and
at least two of the recessed portions overlap each other in a second direction orthogonal to the first direction.

7. The semiconductor module according to claim 6, wherein
the bonding portion has a rectangular shape in the plan view, and
either the first direction or the second direction is parallel to an outer edge of the bonding portion.

8. The semiconductor module according to claim 1, wherein
the bonding portion has a rectangular shape in the plan view, and
each of the plurality of recessed portions is so arranged that two of six inner wall surfaces forming the hexagonal shape thereof in the plan view are parallel to an outer edge of the bonding portion.
